(19) United States
(12) Patent Application Publication
(10) Pub. No.: US 2010/0244200 A1
(43) Pub. Date: Sep. 30, 2010

(54) Integrated circuit connecting structure having flexible layout

(75) Inventors: Tse Ming Chu, Taipei City (TW); Sung Chuan Ma, Tai Po (HK)

Correspondence Address: Jackson Intellectual Property Group PLLC, 106 Starvale Lane, Shipman, VA, 22971, US

(73) Assignees: Chu, Tse Ming, Taipei City (TW); Ma, Sung Chuan, Luzhu Shiang (TW)

(21) Appl. No.: 11/878,437

(22) Filed: Jul. 24, 2007

(51) Int. Cl. H01L 23/48; H01L 23/498

(52) U.S. Cl. 257/620; 257/784; 257/621; 257/E23.065; 257/E23.011

(57) ABSTRACT

A wafer has a cutting part filled with a connecting medium. After the wafer is cut into chips along the cutting part, two contacts on two surfaces of the chip can be connected through corresponding leading wires and the connecting medium. Thus, the chip can have a flexible layout.

### FIELD OF THE INVENTION

The present invention relates to integrated circuit (IC) connection; more particularly, relates to connecting two contracts on two surfaces of a chip through corresponding leading wires and a connecting medium to obtain a flexible layout.

### DESCRIPTION OF THE RELATED ART

A prior art is disclosed. A semiconductor chip is deposed on a substrate having a plurality of solder joints. The chip has a surface with a plurality of solder lands located not corresponding to the solder joints. A steel plate is put on the surface having the solder lands. And a plurality of through holes is formed on the steel plate to expose a part of the corresponding solder lands and the surface having the solder lands. Thus, a space for a conductive object is formed between the walls of the through holes of the steel plate and the surface having the solder lands. Then a conductive object is formed in the space through a printing method with a material of conductive metal adhesive. Therein, the conductive object has an extending part extending out to be a circuit track; and an electric connector at a free end of the extending part located corresponding to the solder joint of the substrate. Thus, a problem of a too small distance between solder joints for electrically connecting an outside circuit is solved.

Although the prior art solves the problem of the small distance between the solder joints, a single chip still has connections on one surface only. When chips are piled up and thus connections between two surfaces are necessary, a complex manufacturing process or design may be required. Hence, the prior art does not fulfill all users' requests on actual use.

### SUMMARY OF THE INVENTION

The main purpose of the present invention is to cut a wafer into chips along a cutting part to connect two contracts separately on two surfaces of a chip through corresponding leading wires and a connecting medium for obtaining a flexible layout.

To achieve the above purpose, the present invention is an IC connecting structure having a flexible layout, comprising a wafer having a plurality of contacts on each of two surfaces; at least one cutting part at a proper place of the wafer, comprising a plurality of through holes aligned into a line; a connecting medium located in the cutting part; and a plurality of leading wire connecting the contact and the connecting medium. Accordingly, a novel IC connecting structure having a flexible layout is obtained.

### BRIEF DESCRIPTION OF THE DRAWINGS

The present invention will be better understood from the following detailed description of the preferred embodiment according to the present invention, taken in conjunction with the accompanying drawings, in which

FIG. 1 is the view showing cutting the wafer according to the preferred embodiment of the present invention;

FIG. 2 is the perspective view showing the chip obtained after the cutting;

FIG. 3 is the sectional view showing the chip;

FIG. 4 is the view showing the state of stacking the chips;

FIG. 5 is the view showing another state of stacking the chips;

FIG. 6 is the view showing cutting the wafer in another state of use; and

FIG. 7 is the perspective view showing the chip in another state of use.

### DESCRIPTION OF THE PREFERRED EMBODIMENT

The following description of the preferred embodiment is provided to understand the features and the structures of the present invention.

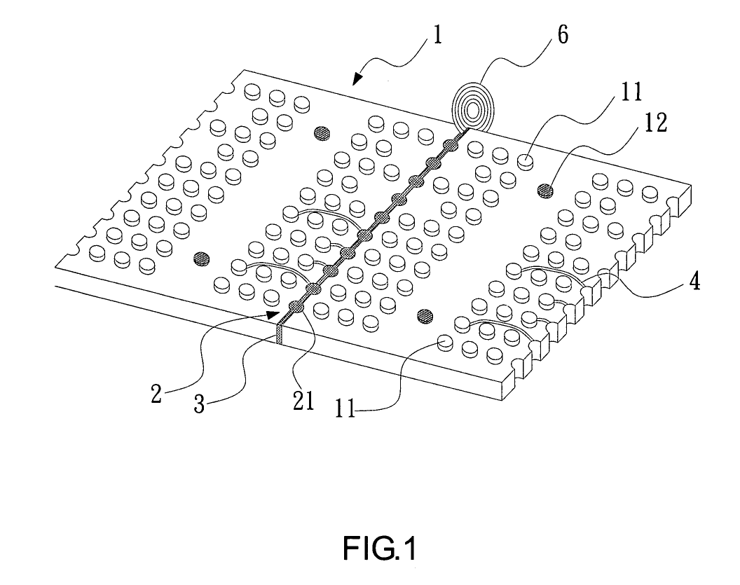

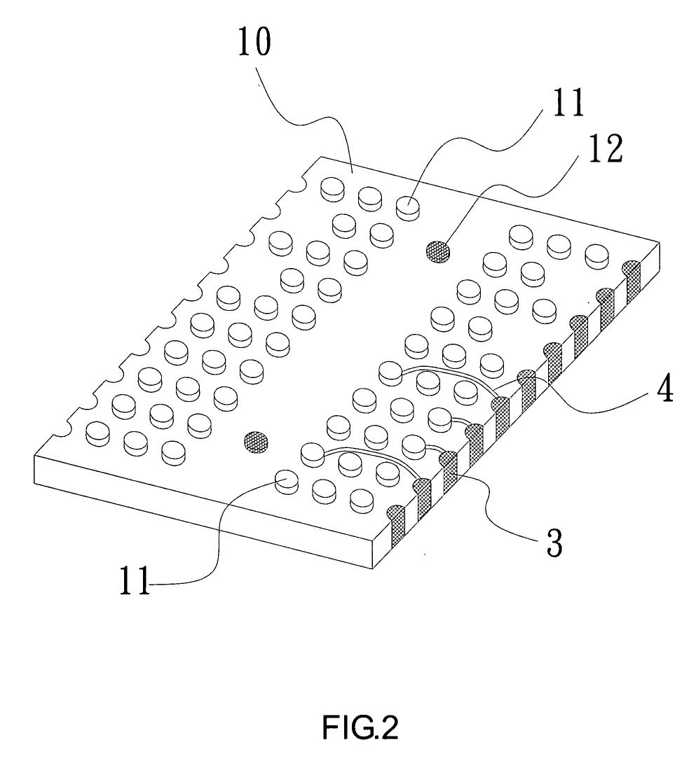

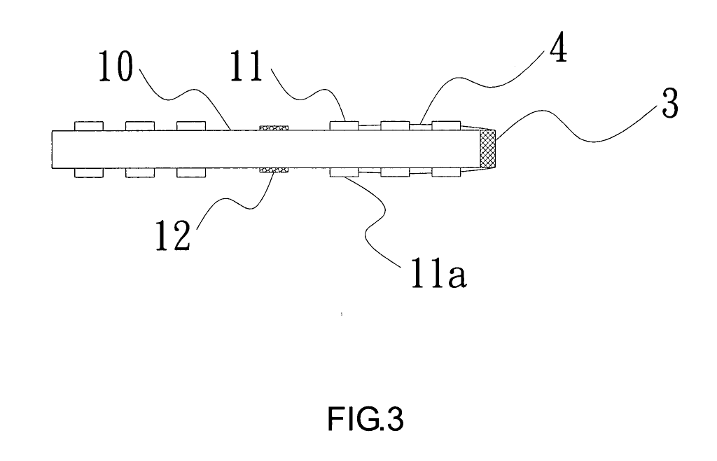

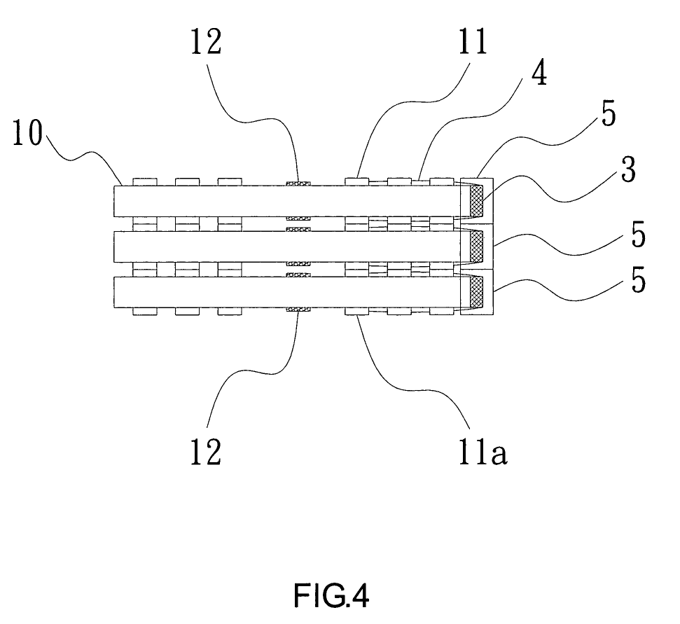

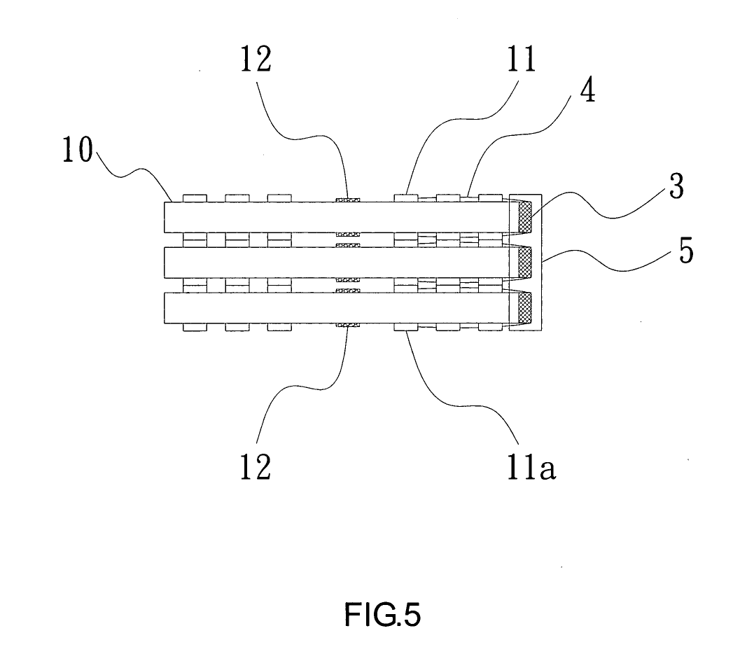

Please refer to FIG. 1 to FIG. 5, which are a view showing cutting a wafer according to the preferred embodiment of the present invention; perspective view showing a chip obtained after cutting the wafer; a sectional view showing the chip; a view showing a state of stacking the chips; and a view showing another state of stacking the chips. As shown in the figures, the present invention is an integrated circuit (IC) connecting structure having a flexible layout, comprising a wafer 1, at least one cutting part 2, a connecting medium 3 and a plurality of leading wires 4, where chips are obtained by cutting the wafer 1 along the cutting part 2 and two surfaces of the chips are connected through the corresponding leading wires 4 and the connecting medium 3 to obtain a flexible IC layout.

The wafer 1 obtains a plurality of contacts 11,11a on each of two surfaces through a semiconductor manufacturing process; and has a plurality of positioning points 12 on each of the two surfaces.

The cutting part 2 is located at a proper position of the wafer 1; and comprises a plurality of through holes 21, which is aligned into a line for the wafer 1 to be cut into chips.

The connecting medium 3 is located in the cutting part 2 through a semiconductor manufacturing process, where the connecting medium 3 is silver adhesive.

Each of the leading wires 4 is connected to a contact 11,11a on either surface of the wafer 1 at an end and is connected to the connecting medium 3 at another end so that two contracts separately on two surfaces are connected through two corresponding leading wires 4 and the connecting medium 3. Thus, a novel IC connecting structure having a flexible layout is obtained.

On using the present invention, a cutting device 6 is used to cut the wafer 1 along the cutting part 2 into a plurality of chips 10, where the connecting medium 3 is thus located at a side of the chip 10. Hence, two contacts 11,11a separately on two surfaces of the chip are connected through two corresponding leading wires 4 and the connecting medium 3 and thus the chips 10 are used as piled-up.

When the chips 10 are used as piled-up, the chips 10 are positioned through positioning points 12 to connect contacts on the surfaces of the chips. A protecting layer 5 is covered at a side of each chip 10 where the connecting medium 3 is located. Or, a protecting layer 5 is covered at a side of all chips 10 where the connecting mediums 3 are located. Thus, the chip has its two surfaces connected through the connecting medium 3 and the leading wire 4 to obtained a flexible IC layout.

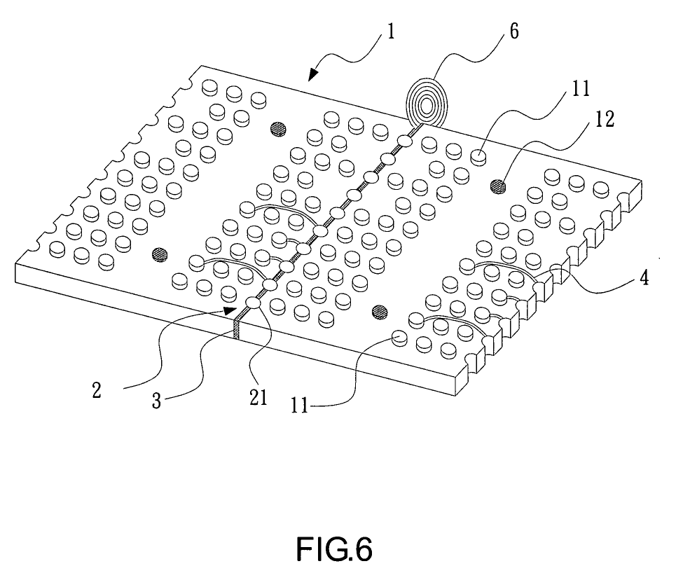

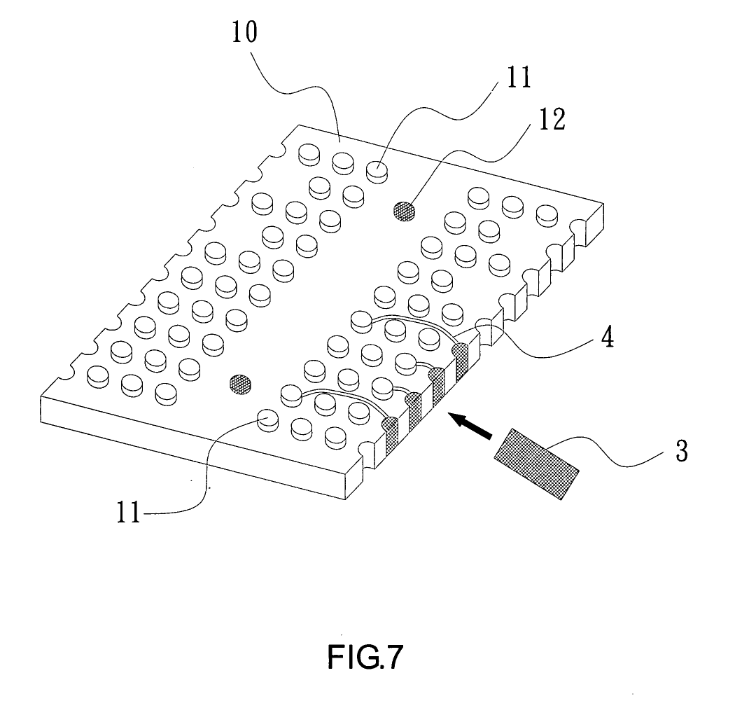

Please refer to FIG. 6 and FIG. 7, which are a view showing cutting the wafer in another state of use; and a perspective view showing the chip in another state of use. As shown in the figures, a connecting medium 3 not only can be obtained in a cutting part 2 of a wafer 1 through a semiconductor manufacturing process, but also the connecting medium 3 can be dripped at a side of the chip 2 (the original cutting part 2) to connect two contacts 11,11a separately on two surfaces of the chip 10 after the wafer 1 is cut into chips 2 by a cutting device 6.

To sum up, the present invention is an IC connecting structure having a flexible layout, where a wafer is cut into chips along a cutting part and contacts separately on two surfaces of the chip are connected through corresponding leading wires and a connecting medium to obtain a flexible IC layout.

The preferred embodiment herein disclosed is not intended to unnecessarily limit the scope of the invention. Therefore, simple modifications or variations belonging to the equivalent of the scope of the claims and the instructions disclosed herein for a patent are all within the scope of the present invention.

What is claimed is:

1. An integrated circuit connecting structure having a flexible layout, comprising
a wafer, said wafer having a plurality of contacts on each of two surfaces of said wafer;
at least one cutting part, said cutting part being located at a position of said wafer, said cutting part having a plurality of through holes aligned into a line to have said wafer be cut;
a connecting medium, said connecting medium being located in said cutting part; and
a plurality of leading wires, an end of said leading wire being connected with said contact on a surface of said wafer, another end of said leading wire being connected with said connecting medium, two contacts separately deposed on two surfaces of said wafer being connected with each other through two corresponding leading wires and said connecting medium.

2. The structure according to claim 1,
wherein said wafer obtains said contacts on said two surfaces through a semiconductor manufacturing process.

3. The structure according to claim 1,
wherein said wafer has a plurality of positioning points on each surface of said wafer.

4. The structure according to claim 1,
wherein said through holes are round through holes.

5. The structure according to claim 1,
wherein said through holes are rectangular through holes.

6. The structure according to claim 1,
wherein said connecting medium is located in said through holes through a semiconductor manufacturing process.

7. The structure according to claim 1
wherein said connecting medium is silver adhesive.

8. An IC connecting structure having a flexible layout, comprising
a chip, said chip having a plurality of contacts on each of two surfaces of said chip;
a connecting medium, said
connecting medium being located on a side surface of said chip;
a plurality of leading wires, an end of said leading wire being connected with said contact on a surface of said chip, another end of said leading wire being connected with said connecting medium, two contacts separately deposed on two surfaces of said chip being connected with each other through two corresponding leading wires and said connecting medium; and
a protecting layer, said protecting layer being located at said side of said chip to cover said connecting medium.

9. The structure according to claim 9,
wherein said chip has a plurality of positioning points on each surface of said chip.

10. The structure according to claim 9,
wherein said wafer obtains said contacts on said two surfaces through a semiconductor manufacturing process.

11. The structure according to claim 9,
wherein said connecting medium is located at a side of said chip through a semiconductor manufacturing process.

12. The structure according to claim 9,
wherein said connecting medium is silver adhesive.
